(19) United States
(12) Patent Application Publication
(10) Pub. No.: US 2026/0371535 A1
(43) Pub. Date: Nov. 19, 2026

(54) ENERGY STORAGE MODULE

(71) Applicant: VERTIV CORPORATION, Westerville, OH (US)

(72) Inventors: Connor Mullenax, Westerville, OH (US); Lucas Wells, Westerville, OH (US); Adam W. Meyer, Columbus, OH (US); Zachary Kreft, Westerville, OH (US); William M. Dixon, Lewis Center, OH (US); Vishal Ravindra Agiwale, Westerville, OH (US)

(21) Appl. No.: 19/576,929

(22) Filed: Mar. 24, 2026

Related U.S. Application Data
(60) Provisional application No. 63/805,533, filed on May 14, 2025.

(51) Int. Cl. H05K 7/20; H02J 1/10; H02J 1/16; H02M 3/00; H05K 7/14; H02J 105/42

(52) U.S. Cl. CPC H05K 7/20909; H02J 1/106; H02J 1/16; H02M 3/003; H05K 7/1432; H05K 7/1492; H02J 2105/425

(57) ABSTRACT

A power module may include a power module housing. The power module may include a power connector configured to receive an input power. The power module may include one or more energy storage packs configured to store the input power, wherein at least one of the one or more energy storage packs comprises a plurality of energy storage cells. The power module may include a battery management system configured to monitor a status of the one or more energy storage packs. The power module may include at least one controller configured to control a release of energy from the one or more energy storage packs. The power module may include a direct-current to direct current converter configured to convert the energy from the one or more energy storage packs into an output power. The power module may include one or more fans configured to circulate air within the power module.

### CROSS-REFERENCE TO RELATED APPLICATIONS

The present application claims the benefit under 35 U.S.C. § 119(e) of U.S. Provisional Patent Application Serial Number 63/805,533 filed May. 14, 2025, titled “ENERGY STORAGE MODULE”, which is incorporated herein by reference in its entirety.

### TECHNICAL FIELD

The present disclosure relates to power control systems for electronic equipment, and more particularly to power control for one or more components of a powertrain.

### BACKGROUND

Server farms often rely on one or more uninterruptible power supplies (UPS) to deliver power to each server. Many of these servers have variable loads, such as variable loads for servers used for data collection and training for artificial intelligence (AI)-based platforms. The variable loads are cyclic, often including a high-load element and a low-load element. For example, during data collection cycles, the power required by AI platforms is relatively small, with processors operating often running under less than the rated power level (e.g., a low-load element of 10% to 30% rated power). Once the data collection cycle is complete, a machine learning (ML) training process starts (e.g., a high-load element), with power used by processors reaching 100% of the rated power level and may even exceed the rated power level for short durations. The training process is then maintained for a period of time (e.g., 100 ms to 1 second) before the power drops back down to drops back down to lower power levels, such as the lower power levels of the data collection cycle. These load cycles of high-load elements and low-load elements may last several minutes up to, and more than, several hours. Alternating between periods of load cycling are low-activity interim periods where the server processors operate consistently at low power.

Power to the server processors is maintained through these load fluctuations by the power components of the powertrain, such as the UPS, which rely on batteries to provide continuous power. Cycling of loads between high-load elements and low-load elements can cause repeated discharges, or discharge cycles, from the batteries that eventually deplete energy from the battery. Battery life in power components may be reduced as the number of discharge cycles increases. Therefore, there is a need for power components that reduce the number or severity of discharge cycles, particularly for power components that power variable loads, such as variable loads used by servers running AI-based applications.

### SUMMARY

Accordingly, the present disclosure is directed toward a power module, in accordance with one or more embodiments of the disclosure. In one or more embodiments, the power module includes a power module housing, a power connector configured to receive an input power: one or more energy storage packs configured to store the input power, wherein at least one of the one or more energy storage packs includes a plurality of energy storage cells, a battery management system configured to monitor a status of the one or more energy storage packs; at least one controller configured to control a release of energy from the one or more energy storage packs; a direct current to direct current (DC-DC) converter configured to convert the energy from the one or more energy storage packs into an output power, and one or more fans configured to circulate air within the power module.

In one or more embodiments, a power system is disclosed, In one or more embodiments, the power system includes one or more power module shelves configured to house a plurality of power modules, and a plurality of power modules. In one or more embodiments, the one or more power modules includes one or more energy storage packs configured to receive an input power, a (DC-DC) converter configured to receive stored power from the one or more energy storage packs and convert the stored power into an output power, a battery management system configured to monitor a status of the one or more energy storage packs, at least one controller configured to control a release of output power from the one or more energy storage packs; and a power connector electrically coupled to the one or more energy storage packs and configured to receive the input power and send the output power.

It is to be understood that both the foregoing general description and the following detailed description are exemplary and explanatory only and are not necessarily restrictive of the present disclosure. The accompanying drawings, which are incorporated in and constitute a part of the specification, illustrate subject matter of the disclosure. Together, the descriptions and the drawings serve to explain the principles of the disclosure.

### BRIEF DESCRIPTION OF THE DRAWINGS

The detailed description is described with reference to the accompanying figures. The use of the same reference numbers in different instances in the description and the figures may indicate similar or identical items. Various embodiments or examples ("examples") of the present disclosure are disclosed in the following detailed description and the accompanying drawings. The drawings are not necessarily to scale. In general, operations of disclosed processes may be performed in an arbitrary order, unless otherwise provided in the claims.

FIG. 1A illustrates a block diagram of a computer system, in accordance with one or more embodiments of the disclosure.

FIG. 1B illustrates a reverse perspective view of the power sub-system, showing open back doors of a rack housing power sub-system components, in accordance with one or more embodiments of the disclosure.

FIG. 1C illustrates a graph depicting a relationship between input power, load power, and stored power as utilized by the power sub-system in powering a load, such as by the one or more computer racks, in accordance with one or more embodiments of the disclosure.

FIG. 1D is a drawing depicting a perspective front view of a power module 130 of the energy storage module assembly 110, in accordance with one or more embodiments of the disclosure.

FIG. 2A is a drawing depicting a cutaway side view of the power module inserted into a power module shelf, in accordance with one or more embodiments of the disclosure.

FIG. 2B illustrates a close-up view of a side view of the storage energy pack, in accordance with one or more embodiments of the disclosure.

FIG. 2C illustrates a close-up pan view of the storage energy pack, in accordance with one or more embodiments of the disclosure.

FIG. 2D illustrates a cutaway side view of a power module, in accordance with one or more embodiments of the disclosure.

FIG. 3 illustrates a perspective view of an undercarriage of the power module, in accordance with one or more embodiments of the disclosure.

FIGS. 4A-C illustrate views of arrangements of energy storage cells within the storage energy pack, in accordance with one or more embodiments of the disclosure.

FIG. 5 illustrates a perspective view of a storage energy pack that includes the pack housing, in accordance with one or more embodiments of the disclosure.

FIG. 6 illustrates a perspective underside view of a top panel, in accordance with one or more embodiments of the disclosure.

FIG. 7 illustrates a close-up view of a front portion of the power module with a side panel of the power module housing removed, in accordance with one or more embodiments of the disclosure.

FIG. 8A illustrates a perspective view of an end seal of the power module, in accordance with one or more embodiments of the disclosure.

FIG. 8B illustrates a perspective view of the end seal of the power module, with fasteners inserted into the mounting holes, in accordance with one or more embodiments of the disclosure.

FIG. 9A illustrates a perspective view of a set of power modules inserted into the power module shelf, in accordance with one or more embodiments of the disclosure.

FIG. 9B illustrates a perspective view of the blanking plate, in accordance with one or more embodiments of the disclosure.

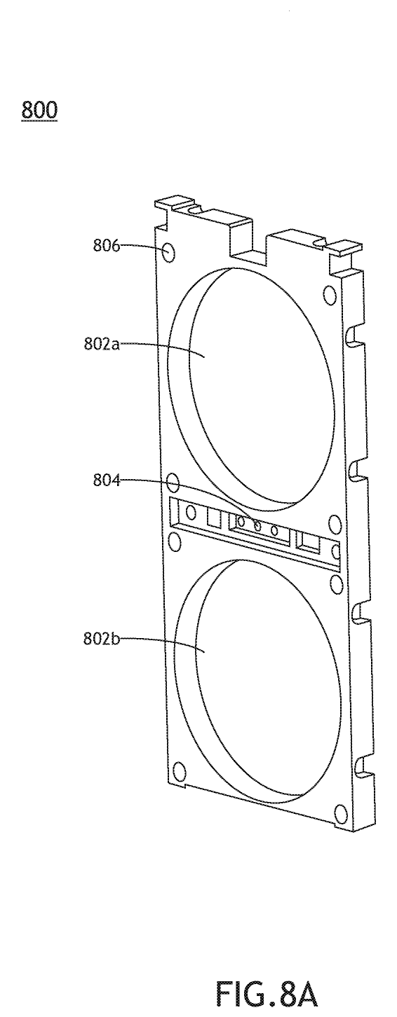

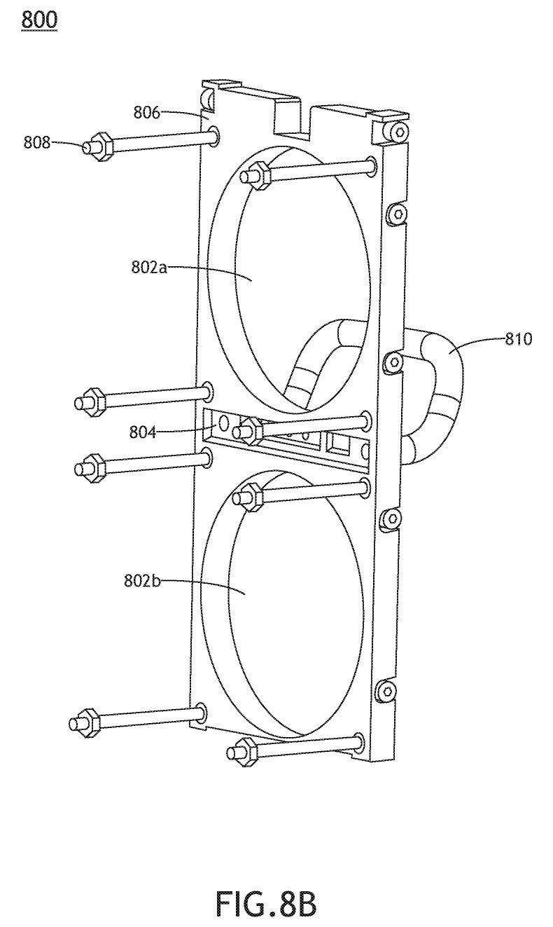

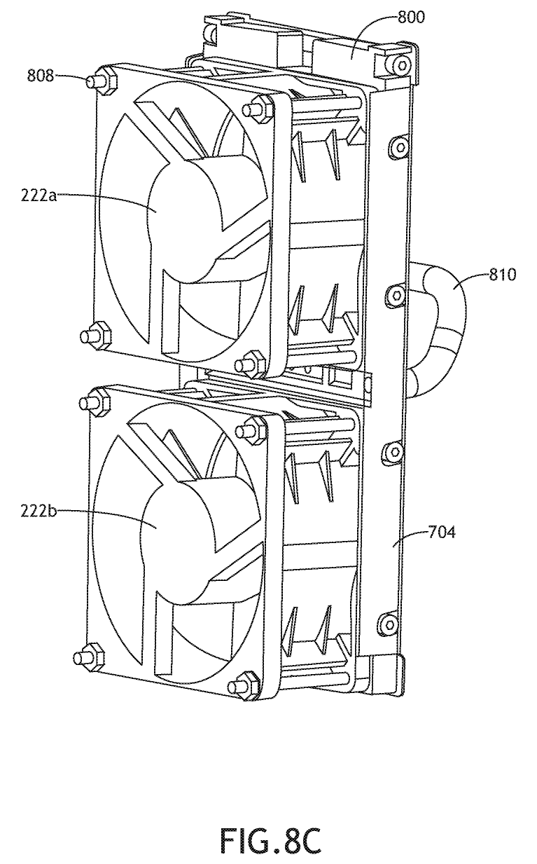

FIG. 8C illustrates a perspective view of the end seal coupled to the vented end plate and fans, in accordance with one or more embodiments of the disclosure.

FIG. 10A illustrates a perspective rear view of the power module shelf, in accordance with one or more embodiments of the disclosure.

FIG. 10B illustrates a perspective rear view of the backplane, in accordance with one or more embodiments of the disclosure.

FIG. 11 illustrates a front view of a power sub-system, in accordance with one or more embodiments of the disclosure.

FIGS. 12A-12C illustrate wired and perspective views, respectively, of an offset standoff, in accordance with one or more embodiments of the disclosure.

FIG. 13 illustrates a simplified schematic of circuitry associated with the power module and the backplane of the power module shelf, in accordance with one or more embodiments of the disclosure.

FIG. 14A illustrates a cutaway side view of a power module, in accordance with one or more embodiments of the disclosure.

FIG. 14B illustrates a cutaway side view of a power module, in accordance with one or more embodiments of the disclosure.

### DETAILED DESCRIPTION

Before explaining one or more embodiments of the disclosure in detail, it is to be understood that the embodiments are not limited in their application to the details of construction and the arrangement of the components or steps or methodologies set forth in the following description or illustrated in the drawings. In the following detailed description of embodiments, numerous specific details may be set forth in order to provide a more thorough understanding of the disclosure. However, it will be apparent to one of ordinary skill in the art having the benefit of the instant disclosure that the embodiments disclosed herein may be practiced without some of these specific details. In other instances, well-known features may not be described in detail to avoid unnecessarily complicating the instant disclosure.

As used herein a letter following a reference numeral is intended to reference an embodiment of the feature or element that may be similar, but not necessarily identical, to a previously described element or feature bearing the same reference numeral (e.g., 1, 1a, 1b). Such shorthand notations are used for purposes of convenience only and should not be construed to limit the disclosure in any way unless expressly stated to the contrary.

Further, unless expressly stated to the contrary, “or” refers to an inclusive or and not to an exclusive or. For example, a condition A or B is satisfied by any one of the following: A is true (or present), and B is false (or not present), A is false (or not present), and B is true (or present), and both A and B are true (or present).

In addition, the use of “a” or “an” may be employed to describe elements and components of embodiments disclosed herein. This is done merely for convenience and “a” and “an” are intended to include “one” or “at least one,” and the singular also includes the plural unless it is obvious that it is meant otherwise.

Finally, as used herein any reference to “one embodiment” or “embodiments” means that a particular element, feature, structure, or characteristic described in connection with the embodiment is included in at least one embodiment disclosed herein. The appearances of the phrase “in embodiments” in various places in the specification are not necessarily all referring to the same embodiment, and embodiments may include one or more of the features expressly described or inherently present herein, or any combination or sub-combination of two or more such features, along with any other features which may not necessarily be expressly described or inherently present in the instant disclosure.

Disclosed is a power module for providing electrical smoothing and/or temporary backup power for electrical components, such as server racks. The power module includes power storage packs that include battery and/or supercapacitor cells that store electrical power. The power module further includes DC-DC converters and other electronic componentry (e.g., battery management systems and energy control boards) that ensure safe and effective control of electrical power to and/or from the power storage packs. The power modules are configured to fit into a power shelf, which itself is configured to fit into a power rack. The organization of the componentry within the power module provides an efficient, energy-dense, yet thermally viable solution for providing high power smoothing systems in a compact structure.

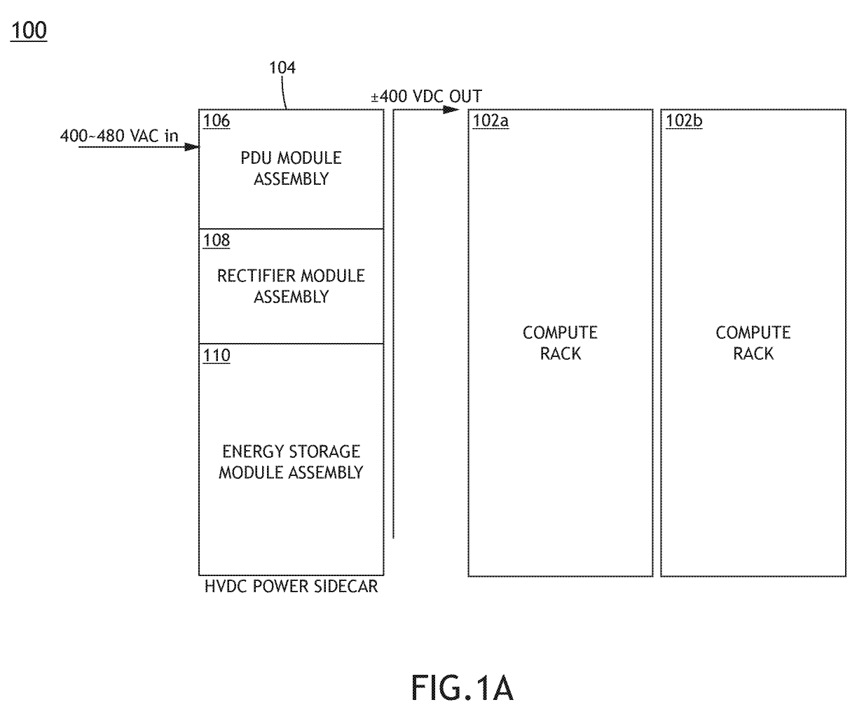

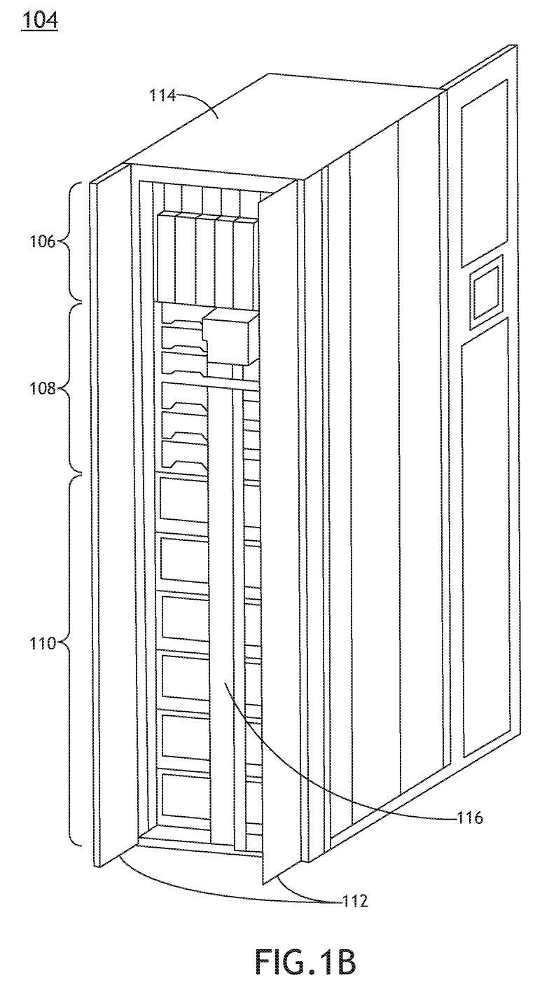

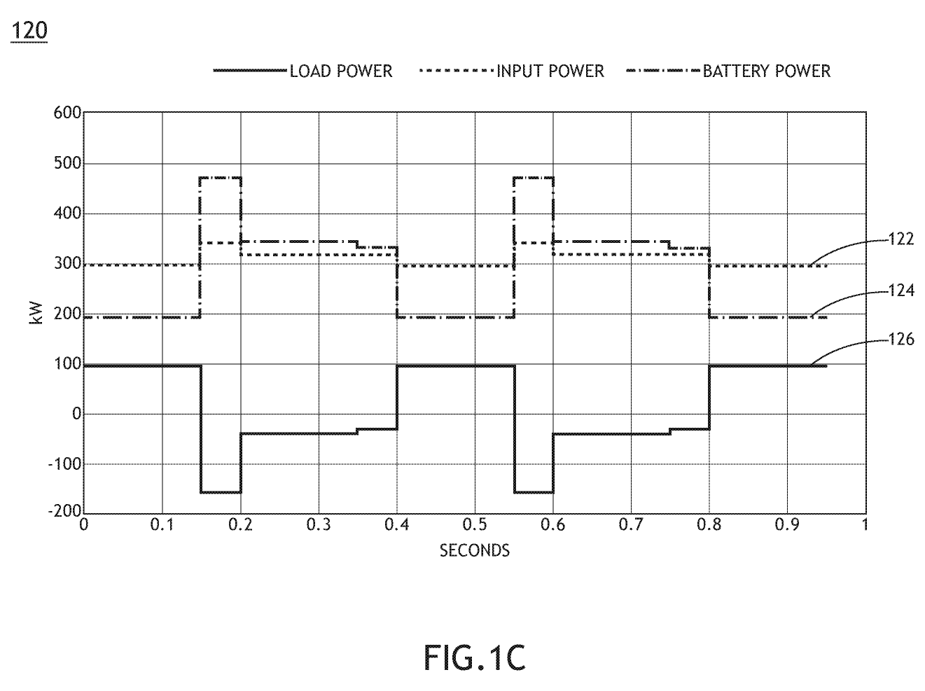

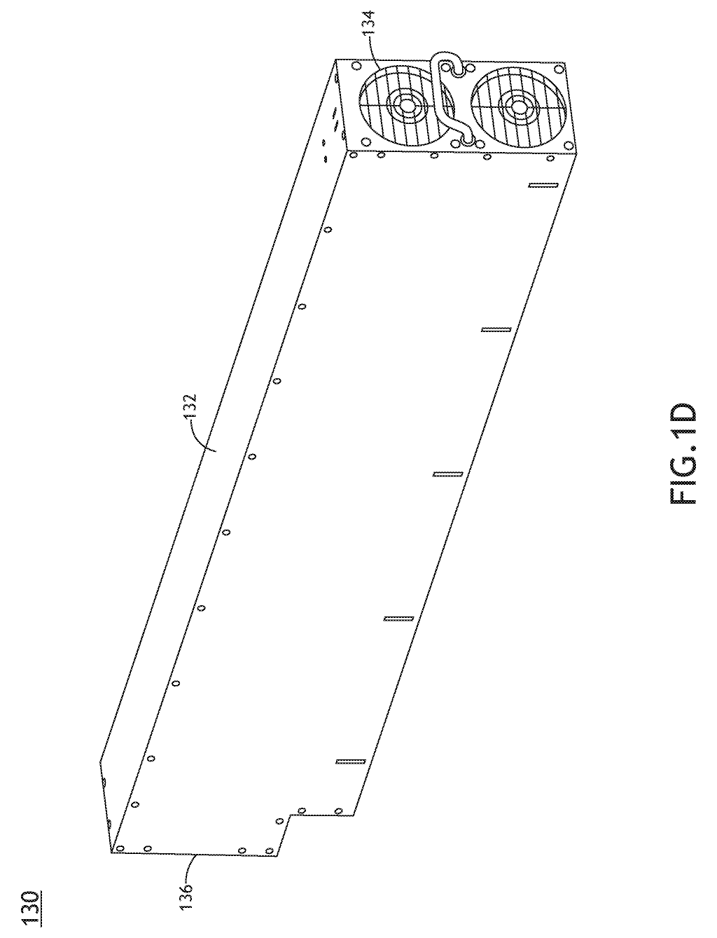

FIG. 1A illustrates a block diagram of a computer system 100, in accordance with one or more embodiments of the disclosure. The computer system 100 may include one or more computer racks 102a, 102b, and one or more power sub-systems 104 (e.g., a “sidecar” rack) configured to power the one or more computer racks 102a, 102b. The one or more computer racks 102a, 102b may include one or more computers, such as servers used in data centers. The power sub-system 104 may be configured to receive power (e.g., mains or utility power), convert the power (e.g., from alternating current (AC) to direct current (DC), and distribute the received power to the one or more computer racks 102a, 102b. For example, the power sub-system 104 may be configured to receive an AC voltage of approximately 400 to 480 volts and distribute power having approximately 400 volts. In another example, the power sub-system 104 is configured to accommodate up to 1000 kW of power. The power sub-system 104 may include a power distribution module assembly 106 configured to receive and/or distribute power, a rectifier module assembly 108 configured to convert AC power to DC power, and an energy storage module assembly 110 configured for conditioning (smoothing) the power to be delivered to the one or more computer racks 102a, 102b. The one or more power sub-systems 104 may be configured to utilize hot-swappability, allowing components to be plugged in and out while the system is online. For example, the one or more power sub-systems 104 may utilize a hot-swappable configuration using Open Rack V3 concepts.

FIG. 1B illustrates a reverse perspective view of the power sub-system 104, showing open back doors 112 of a rack 114 housing power sub-system components, in accordance with one or more embodiments of the disclosure. In embodiments, the rack 114 or the power sub-system 104 includes one or more busbars 116 (e.g., a +/- 400 VDC busbar) configured to distribute power between the components of the power distribution module assembly 106, the rectifier module assembly 108 and/or the energy storage module assembly 110.

FIG. 1C illustrates a graph 120 depicting a relationship between input power 122, load power 124, and stored power 126 as utilized by the power sub-system 104 in powering a load, such as by the one or more computer racks 102a, 102b, in accordance with one or more embodiments of the disclosure. The stored power 126 refers to power stored by the modules of the energy storage module assembly 110. As shown in graph 120, while the input power 122 is fairly constant over time, the load power 124 may swing considerably, stressing componentry of the computer system 100, which can lead to premature faults and lower componentry lifetimes. The modules of the energy storage module assembly 110 may release, or increase the release of, power at intervals of high load power use. The modules of the energy storage module assembly 110 may also reduce, or further reduce, power at intervals of low load power use. By conditioning the flow of power through the electrical system 100 in response to load power 124, the energy storage module assembly 110 is able to ensure that electrical power that is used to power downstream electronic equipment is constant and less variable, reducing stress on these electronic components and increasing component lifespan.

FIG. 1D is a drawing depicting a perspective front view of a power module 130 of the energy storage module assembly 110, in accordance with one or more embodiments of the disclosure. The power module 130 may be insertable and/or hot-swappable within the energy storage module assembly 110 or a shelf within the energy storage module assembly 110 as described herein. The power module 130 includes both power storage and electronics necessary to facilitate power conditioning functions of the energy storage module assembly 110. For example, the power module 130 may be configured to reduce power load surging for the computer system 100 and/or reduce ripple.

In embodiments, the power module 130 includes a power module housing 132 having a front end 134 (e.g., an air intake end) and a back end 136. The front end 134 and/or the back end 136 may include a series of slots or holes that facilitate air flow within the power module 130.

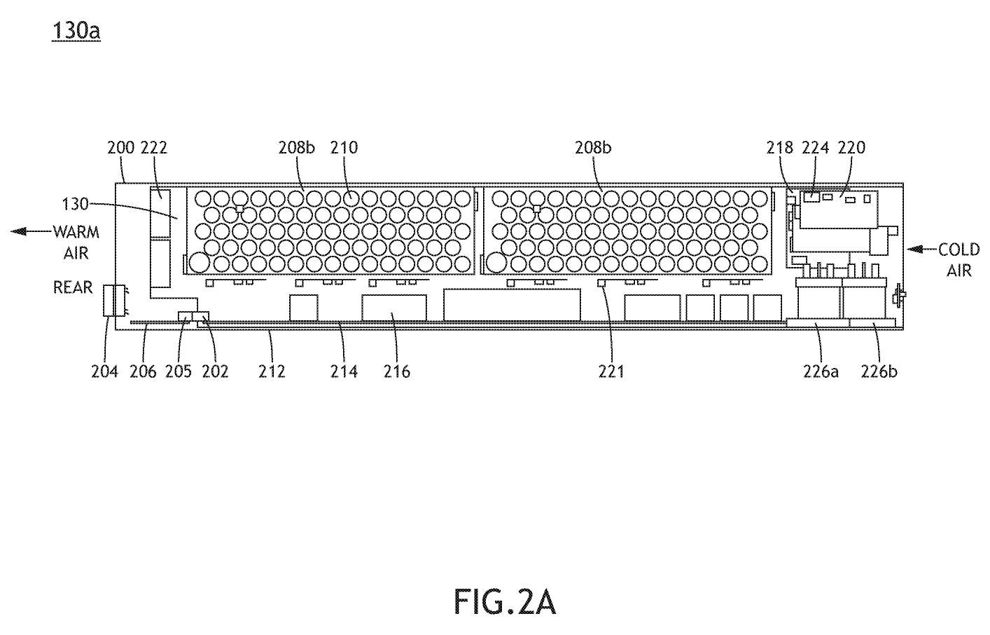

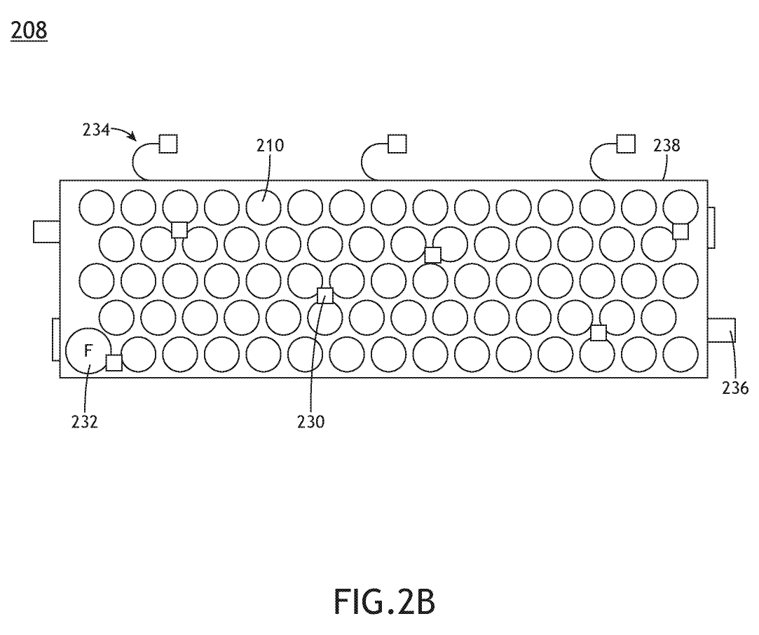

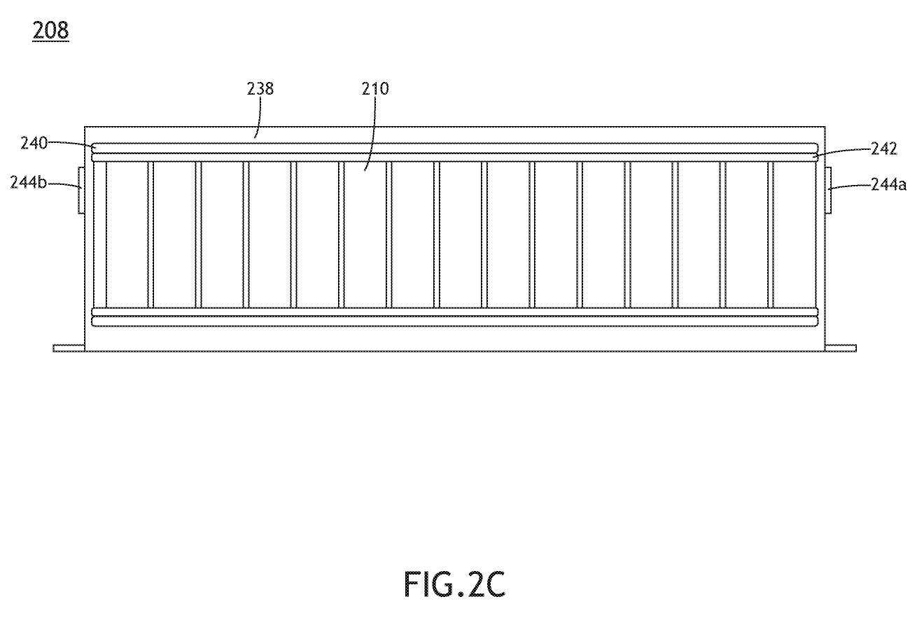

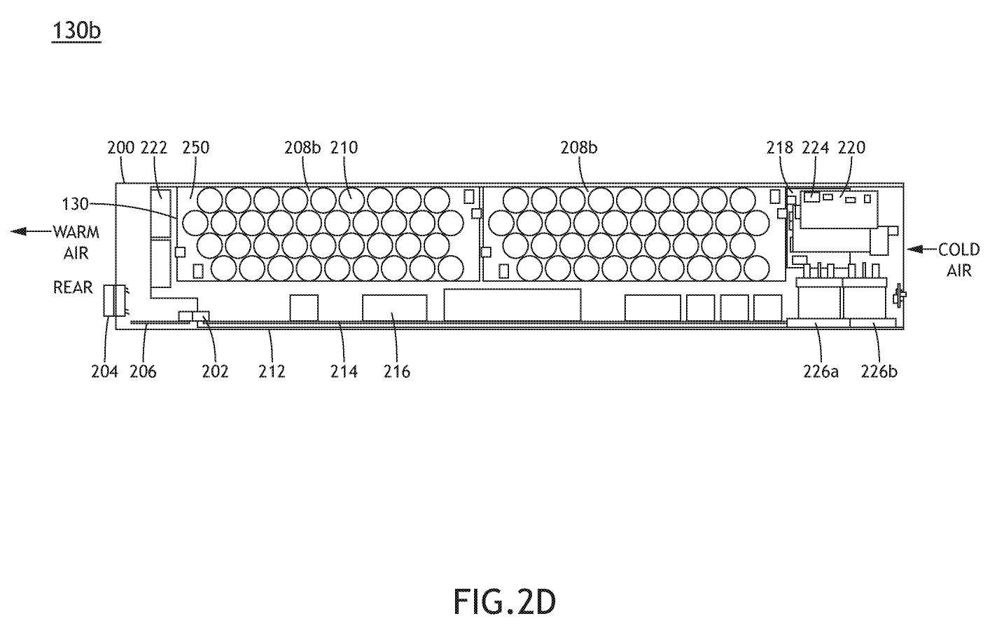

FIG. 2A is a drawing depicting a cutaway side view of the power module 130a inserted into a power module shelf 200 (e.g., the power module shelf 200 shown as an outline), in accordance with one or more embodiments of the disclosure. Once inserted into the power module shelf 200, a power/signal connector 202 of the power module 130a directly or indirectly electrically couples to a power connector 204 (e.g., via a module-shelf connector 205), which in turn is couplable to one or more busbars 116. The power module shelf 200 may be made at least partially of a metal shell and may be configured to house a number of power modules 130a. For example, the power module shelf 200 may be configured to accommodate six power modules 130 (e.g., the power module shelf 200 may include six docking sites for six power modules 130).

In embodiments, the power module shelf 200 includes one or more backplanes 206 that couple to the power/signal connector 202. The backplane may be further coupled to the power connector 204 as well as to other components of the power sub-system 104.

In embodiments, the power module 130a includes one or more energy storage packs 208a, 208b, with each of the one or more energy storage packs including one or more energy storage cells 210. The one or more energy storage packs are configured to receive and store input electrical power (e.g., from the power connector 204) and release the electrical power back into the power sub-system 104 (e.g., during a high load event). The energy storage cells may include any type of power storage technology. For example, the energy storage cell may include a battery, a capacitor, or a supercapacitor. For instance, the energy storage cell 210 may include any type of battery including, but not limited to, lithium-ion (Li-ion) batteries, lead-acid batteries, and nickel-cadmium batteries. In particular, the energy storage cell 210 may include 21700- or 18650-type Li-ion batteries. Energy storage packs 208 containing batteries may further provide backup power for a period of time (e.g., greater than 90 seconds of backup power when input power is lost)

In embodiments, the power module 130a includes a sled 212 configured to anchor one or more electronic components within the power module 130. For example, the sled 212 may be disposed adjacent to, or be coupled to, a printed circuit board 214 (PCB) or material of a similar function that, in turn, is disposed on or coupled to one or more electronic components. The sled 212 may be constructed at least partially of sheet metal, and may be constructed as part of the housing 132.

In embodiments, the power module 130a includes a power converter 216 (e.g., a DC-DC converter). The power converter 216 may be physically coupled to the printed circuit board 214 and configured to convert a stored power (e.g., from the energy storage pack 208) into an output power that may be used for power conditioning. For example, the power converter 216 may receive a DC voltage from the storage energy pack 208 (e.g., from batteries and/or capacitors) and create and/or stabilize an output voltage. For instance, the power converter 216 may stabilize an output of, or up to, 400 volts. The power converter 216 may be excluded from the enclosure that contains the storage energy pack 208 (e.g., the pack housing).

In embodiments, the power module 130a includes an energy control functional safety board (ECF 218) electrically coupled to the one or more energy storage packs 208. The ECF 218 may be configured to monitor and control safety aspects of the storage energy pack 208 and/or energy storage cells 210. In embodiments, the power module 130a includes an energy control secondary board (ECS 220) electrically coupled to the ECF 218 and/or the backplane 206. The ECS 220 may be configured to monitor and control aspects of the storage energy pack 208 and/or energy storage cells 210, such as those aspects not covered by the ECF 218.

In embodiments, the power module includes one or more battery balance managers 221 configured to monitor a status of the storage energy packs 208 and/or energy storage cells 210 within the storage energy packs 208 and facilitate battery balancing protocols or energy balancing protocols when needed.

In embodiments, the power module 130a includes one or more fans 222 and one or more fan control boards 224 electrically coupled to the one or more fans and one or more processors of the power module 130 (e.g., a microprocessor from the ECS 220 and/or the power converter 216. The one or more fans 222 may be configured to circulate air through the power module 130, cooling the interior of the power module 130. The power module 130 may include any number of fans. For example, the power module 130a may have one fan, two fans, three fans, four fans, or five or more fans. The one or more fans 222 may be positioned at any point within the power module 130. For example, the one or more fans 222 may be positioned near the back end 136 of the power module 130a. In another example, the one or more fans 222 may be positioned near the front end 134 of the power module 130a.

In embodiments, the power module 130a includes one or more contactors 226a, 226b electrically coupled to one or more of the one or more energy storage packs 208a, 208b, the power converter 216, and/or the ECF 218. The one or more contactors 226a, 226b may be used to switch circuits off and on within the power module. For example, the one or more contactors 226a, 226b may be used to open and close circuitry between the one or more energy storage packs 208a, 208b and the power converter 216.

FIG. 2B illustrates a close-up view of a side view of the storage energy pack 208, in accordance with one or more embodiments of the disclosure. The storage energy pack 208 may include one or more temperature sensors 230 dispersed within the energy storage cells 210. For example, the one or more temperature sensors 230 may include one or more negative temperature coefficient (NTC) thermistors, resistance temperature detectors (RTDs), thermocouples, and semiconductor-based integrated (IC) sensors. In embodiments, the storage energy pack 208 may further include a fuse 232 (e.g., an in-line fuse), voltage connectors 234, and mounting features 236. The energy storage cells 210 may be stored within a pack housing 238.

FIG. 2C illustrates a close-up pan view of the storage energy pack 208, in accordance with one or more embodiments of the disclosure. In embodiments, the set of energy storage cells 210 are lined at least on one side with a fire suppression material 240. For example, the fire suppression material 240 may include, but not be limited to, ceramic material (e.g., ceramic blankets), mica (e.g., mica tubing or mica sheets), and/or extinguishing patches. Individual energy storage cells 210 may be electrically coupled to each other via a cell bus 242. For example, the cell bus 242 may be welded to the individual energy storage cells 210. In embodiments, the storage energy pack 208 includes terminals 244a, 244b electrically couplable to the main circuitry of the power module 130. The terminals 244a, 244b may be located on opposite sides, or on a same side, of the storage energy pack 208.

FIG. 2D illustrates a cutaway side view of a power module 130b, in accordance with one or more embodiments of the disclosure. Power module 130b may include one or more components of power module 130a, and vice versa.

In embodiments, the power module 130b includes one or more storage energy packs 208 comprising capacitors (e.g., supercapacitors) as the energy storage cell 210. For example, the one or more storage energy packs 208 may include electric double layer capacitors (EDLC). The capacitors actively charge and discharge electrical power during use, allowing the power source (e.g., an AC source) to facilitate an even load despite energy use fluctuations by downstream electronic components, such as GPUs. The capacitors of the storage energy pack 208 may be electrically coupled to a pack circuit board 250.

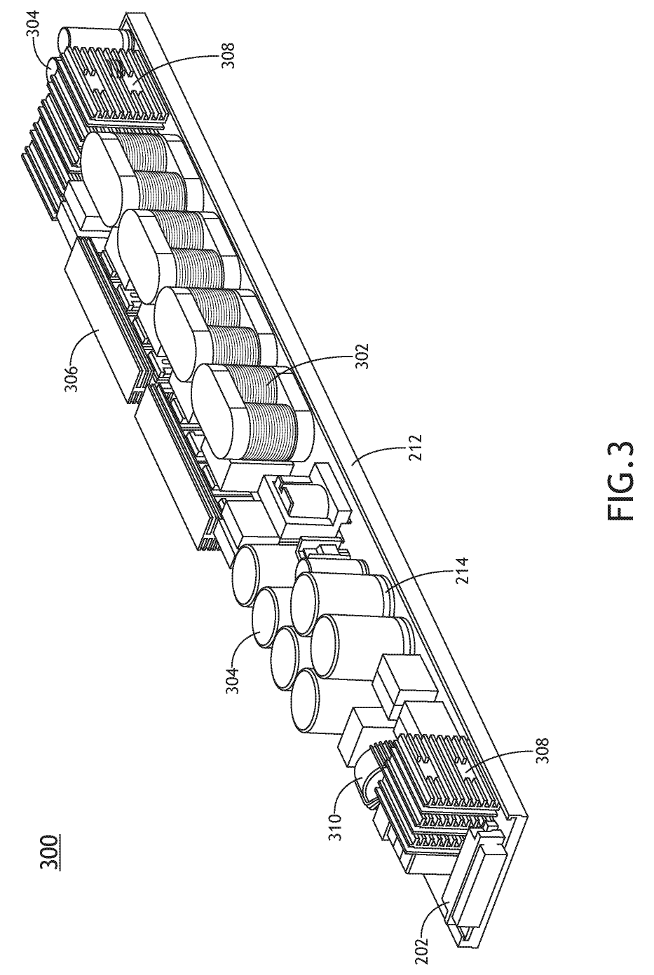

FIG. 3 illustrates a perspective view of an undercarriage 300 of the power module 130, in accordance with one or more embodiments of the disclosure. The undercarriage 300 is disposed below the one more storage energy pack 208, with multiple components positioned on, and/or electrically coupled to, the printed circuit board 214, which resides on the sled 212. The undercarriage 300 may include a series of inductors 302 and capacitors 304, as well as heatsink-mounted transistors 306. The undercarriage may further include one or more transistors 308 (e.g., metal–oxide–semiconductor field-effect transistors (MOSFETs)) and current inductors 310.

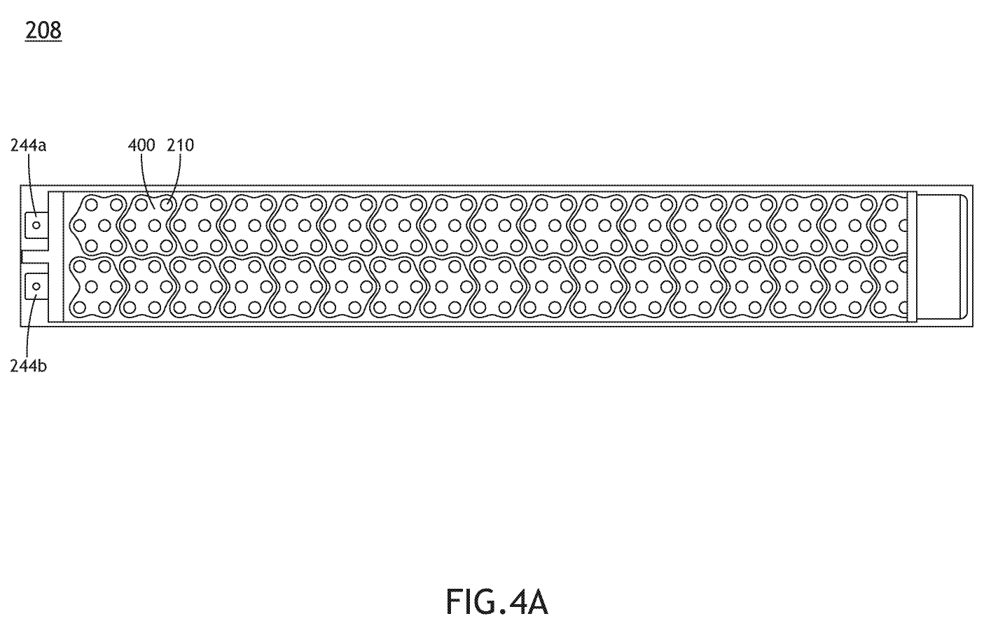

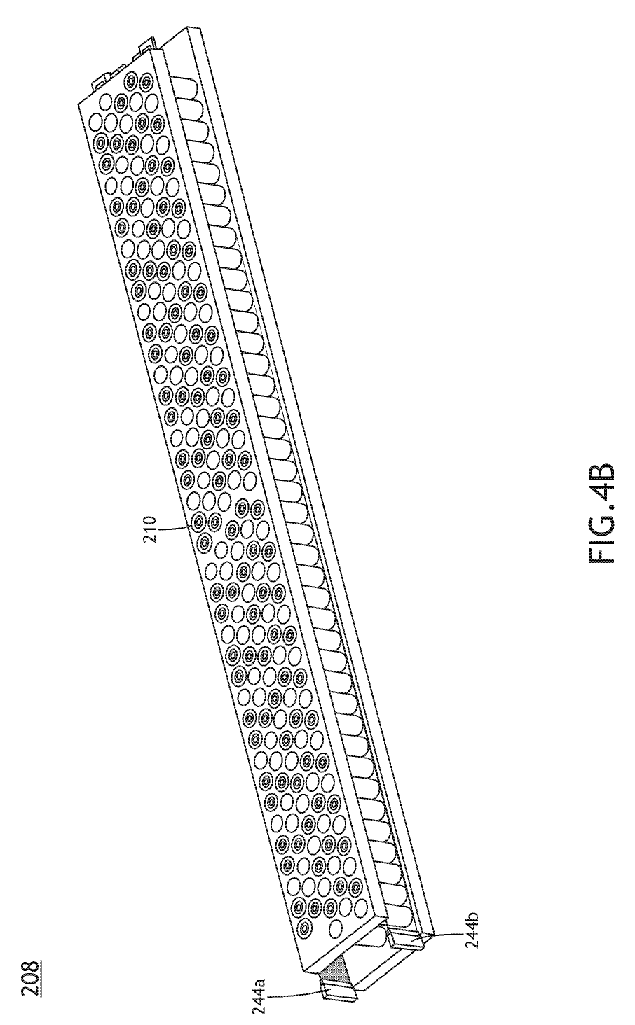

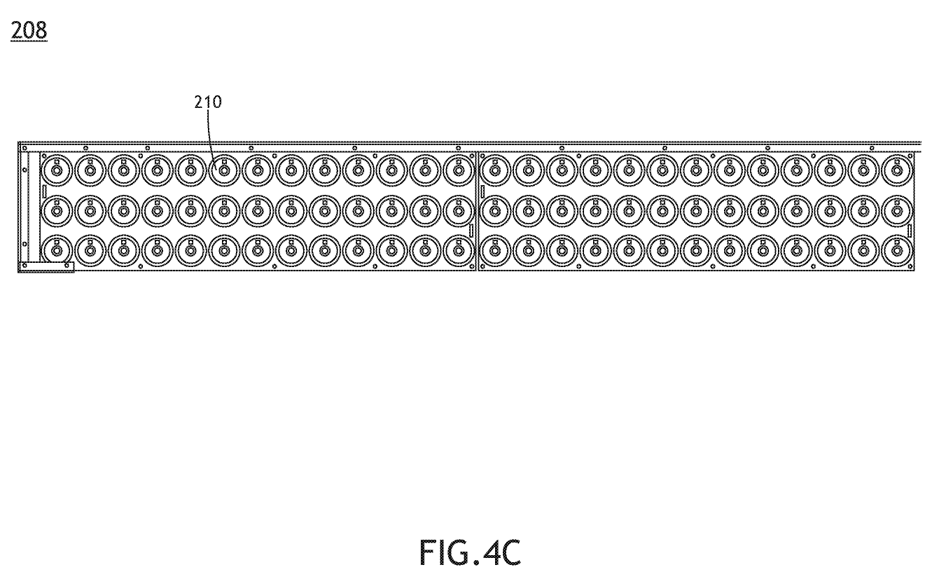

FIGS. 4A to 4C illustrate views of arrangements of energy storage cells 210 within the storage energy pack 208, in accordance with one or more embodiments of the disclosure. For example, the storage energy pack 208 may include energy storage cells 210 arranged in hexagonal clusters 400, as shown in FIG. 4A. The energy storage pack 208 in FIG. 4A further illustrates terminals 244a, 244b (e.g., a positive terminal and a negative terminal) disposed on a single side of the energy storage pack 208. In FIG. 4B, the storage energy pack is shown with energy storage cells 210 arranged in a hexagonal and triangular cell pattern. These spatial geometries may be arranged to maximize and/or optimize power density and minimize overall height.

In FIG. 4C, the energy storage cells 210 (e.g., supercapacitors) are arranged in an array of relatively straight lines and columns. Due to the thermal and electrical properties of the supercapacitors and the allotted space for the storage energy pack 208, the supercapacitors may be set to specific geometries.

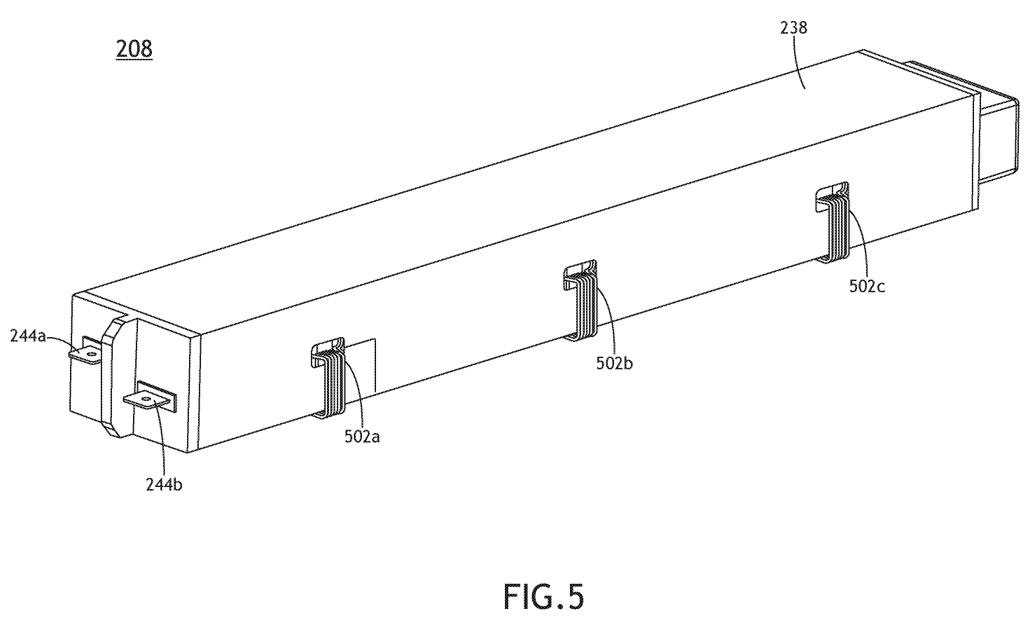

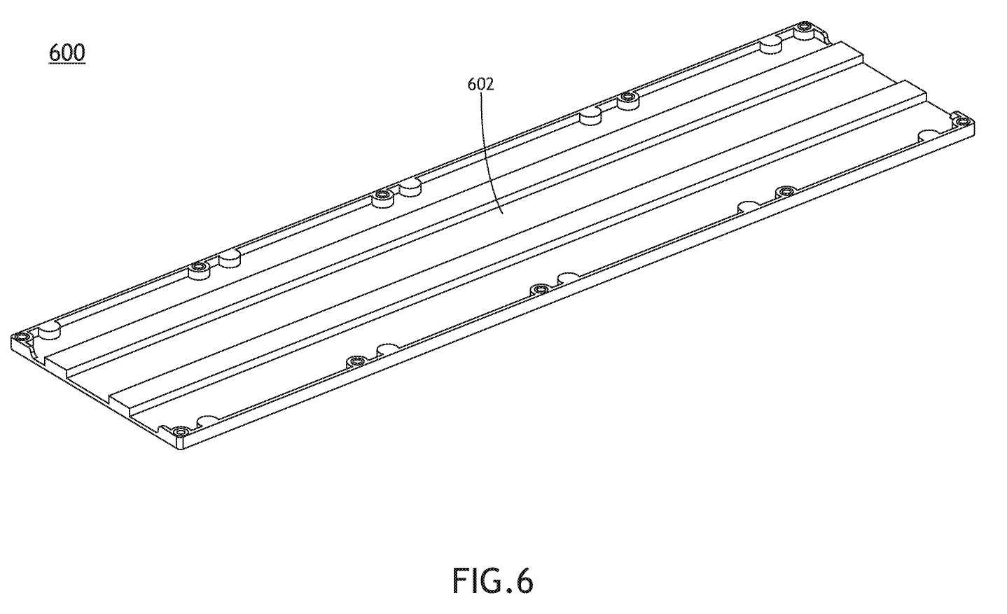

FIG. 5 illustrates a perspective view of a storage energy pack 208 that includes the pack housing 238, in accordance with one or more embodiments of the disclosure. The pack housing 238 may include a metal enclosure (e.g., a steel enclosure) that facilitates fire mitigation. The storage energy pack 208 may include one or more sets of leads 502a, 502b, 502c for electrically coupling power module circuitry to the voltage sensors and temperature sensors 230 within the storage energy pack 208. The pack housing may be configured with a removable cover that facilitates access to the fuses 232 and other componentry within the storge energy pack 208.

FIG. 6 illustrates a perspective underside view of a top panel 600, in accordance with one or more embodiments of the disclosure. The top panel 600 may be configured as a top plate for the power module housing 132 and/or pack housing 238. In embodiments, the top panel 600, as well as other structural panels within the power module 130, includes one or more channels 602. The one or more channels 602 provide space (e.g., as required for specs or regulations) between the housing (e.g., power module housing 132 and/or pack housing 238) and the energy storage cells 210. The one or more channels 602 may further provide airflow passages that facilitate cooling. The one or more channels 602 may further reduce the need for offset standoffs.

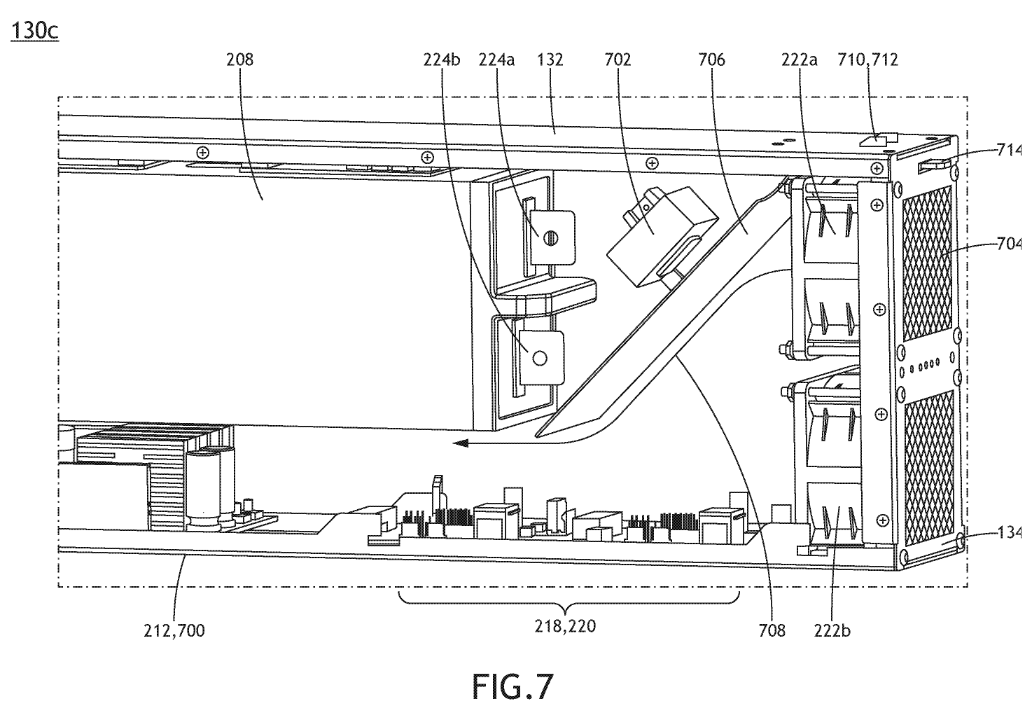

FIG. 7 illustrates a close-up view of a front portion of the power module 130c with a side panel of the power module housing 132 removed, in accordance with one or more embodiments of the disclosure. Power module 130c may include an ECF 218 and/or ECS 220 disposed on the sled 212 and/or bottom panel 700 of the power module housing 132. The power module 130c may include a storage energy pack 208 configured to have both terminals 224a, 224b aligned toward the front end 134. The power module 130c may further include a current transducer electrically coupled to power module circuity and configured to convert current, such as into a voltage for measurement by sensors.

In embodiments, the power module 130c includes fans 222a, 222b disposed adjacent to a vented end plate 704, allowing air (e.g., cool air to be pushed from a front side of the power module 130c to the rear. The power module 130c may further include a baffle 706 configured to direct or guide airflow from the fans 222a, 222b toward the electronic components along the sled 212 (e.g., via a path 708), and away from the one or more energy storage packs 208. For example, the baffle may be placed adjacent to the air intake end (e.g., front end) of the power module 130c.

In embodiments, the power module 130c includes a lock mechanism 710 that secures the power module 130 into place when inserted into the power module shelf 200. For example, the lock mechanism 710 may include prongs 712 that are configured to be biased into a recess within the power module shelf 200, preventing the power module 130c from releasing from the power module shelf 200. The power module 130c may further include a release 714 (e.g., a push button), that causes the lock mechanism 710 to unlock.

FIG. 8A illustrates a perspective view of an end seal 800 of the power module 130c, in accordance with one or more embodiments of the disclosure. The end seal 800 provides an air seal to the power module 130, reducing the backflow of air out of the power module 130c. The end seal 800 may include one or more apertures 802a, 802b configured to line up with the fans 222a, 222b. The end seal may further include an opening set 804 allowing indicator lights from the power module 130c to illuminate past the end seal. The end seal 800 may also include a set of mounting holes 806.

FIG. 8B illustrates a perspective view of the end seal 800 of the power module 130c, with fasteners 808 inserted into the mounting holes 806, in accordance with one or more embodiments of the disclosure. The fasteners 808 may include any type of fastening technology including, but not limited to, bolts and screws. The end seal 800 may further include, or be couplable to, a handle 810 that can be grabbed by a user to facilitate removal of the power module 130c from the power module shelf 200. FIG. 8C illustrates a perspective view of the end seal coupled to the vented end plate 704 and fans 222a-b, in accordance with one or more embodiments of the disclosure.

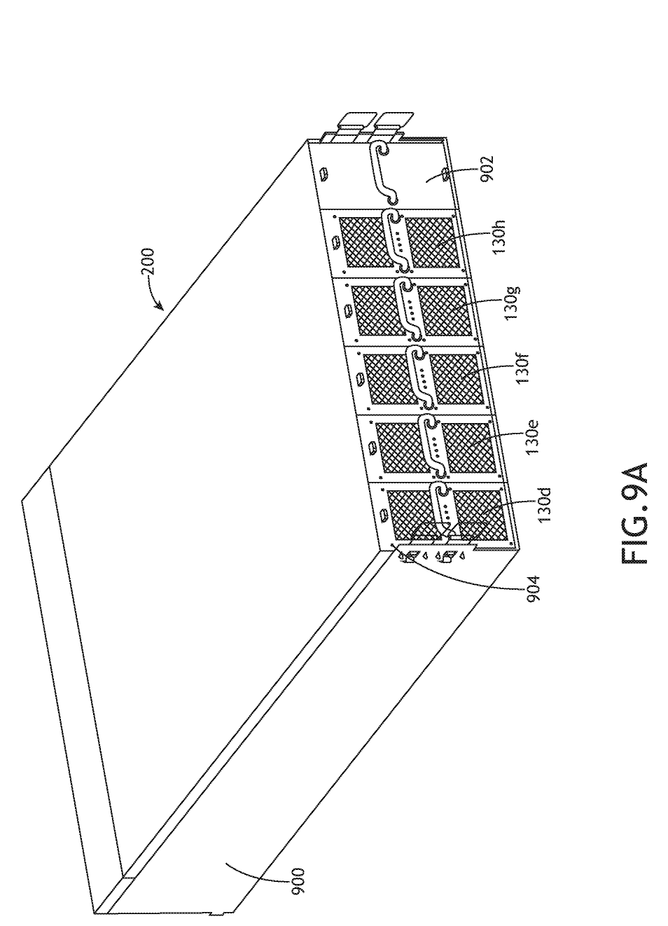

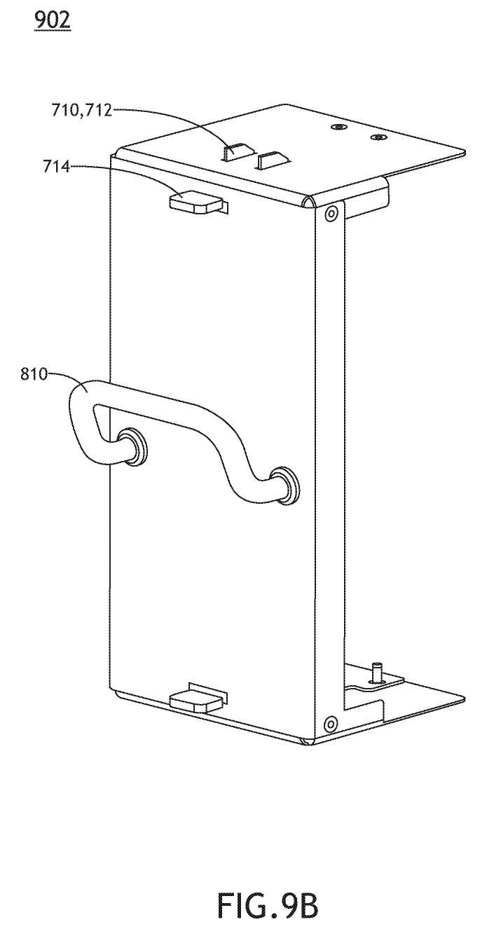

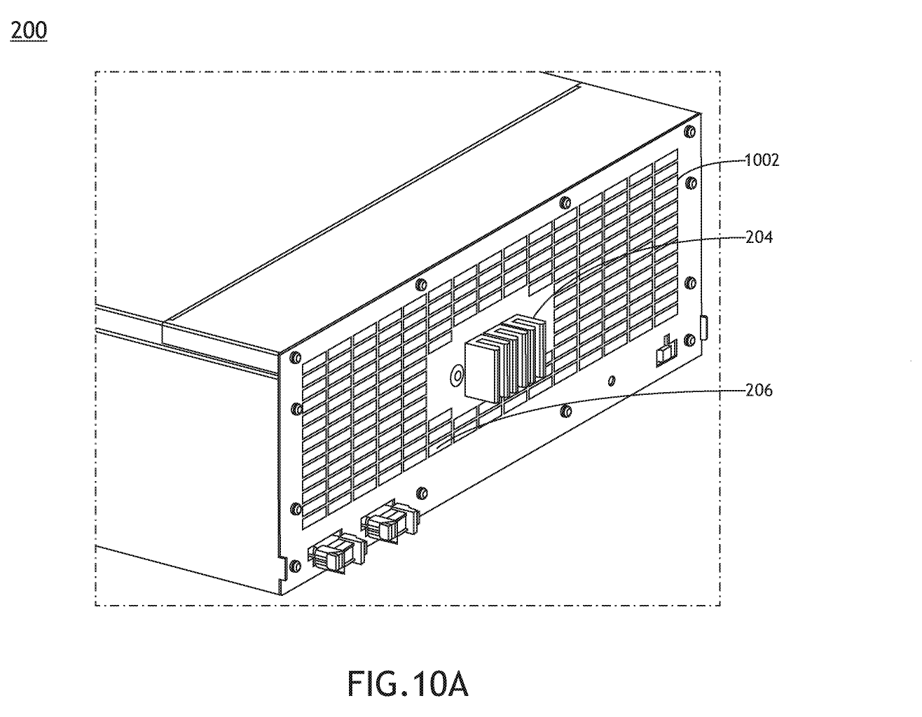

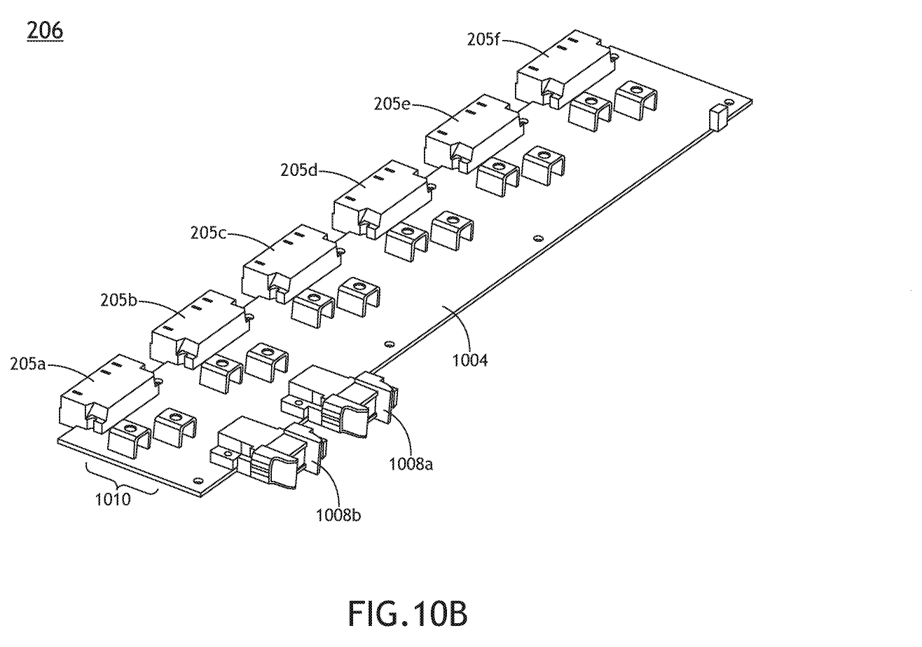

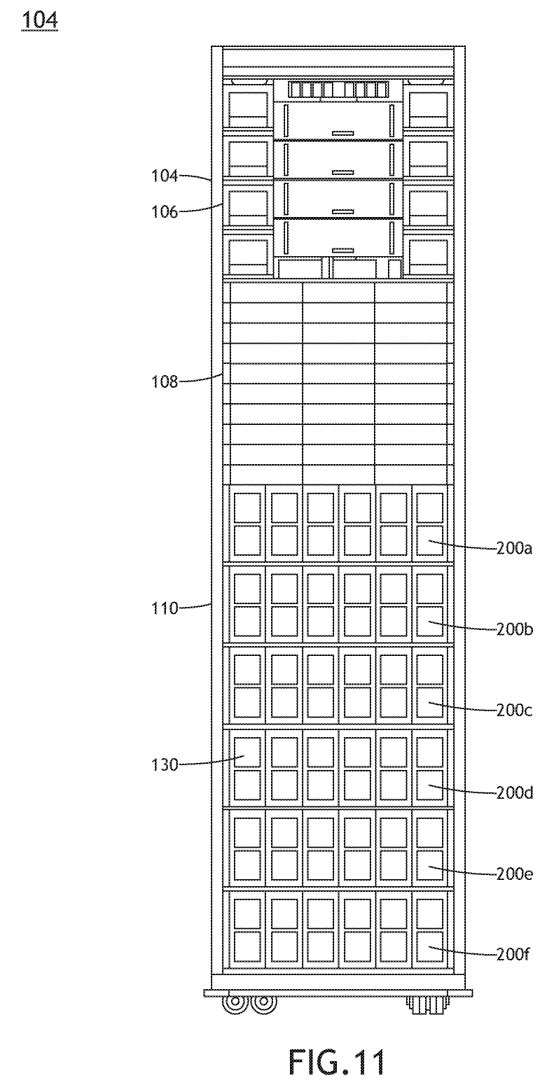

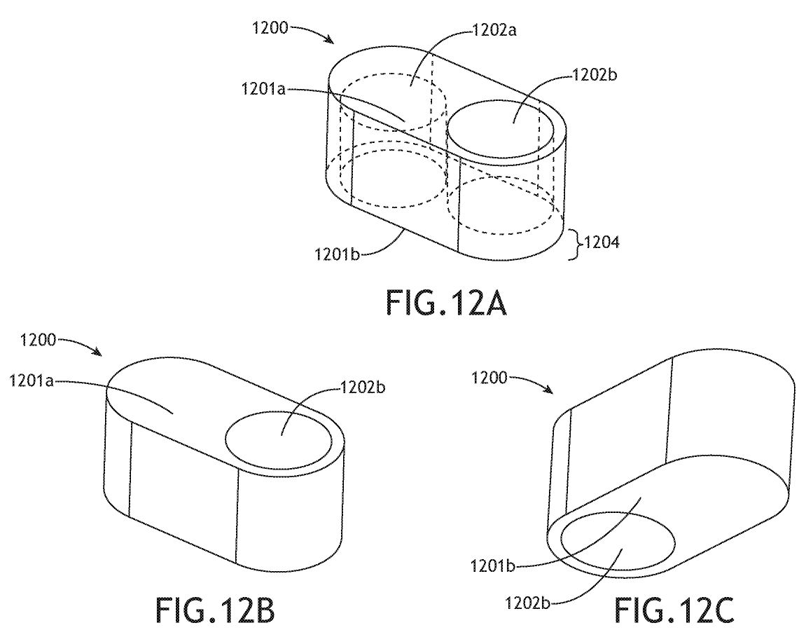

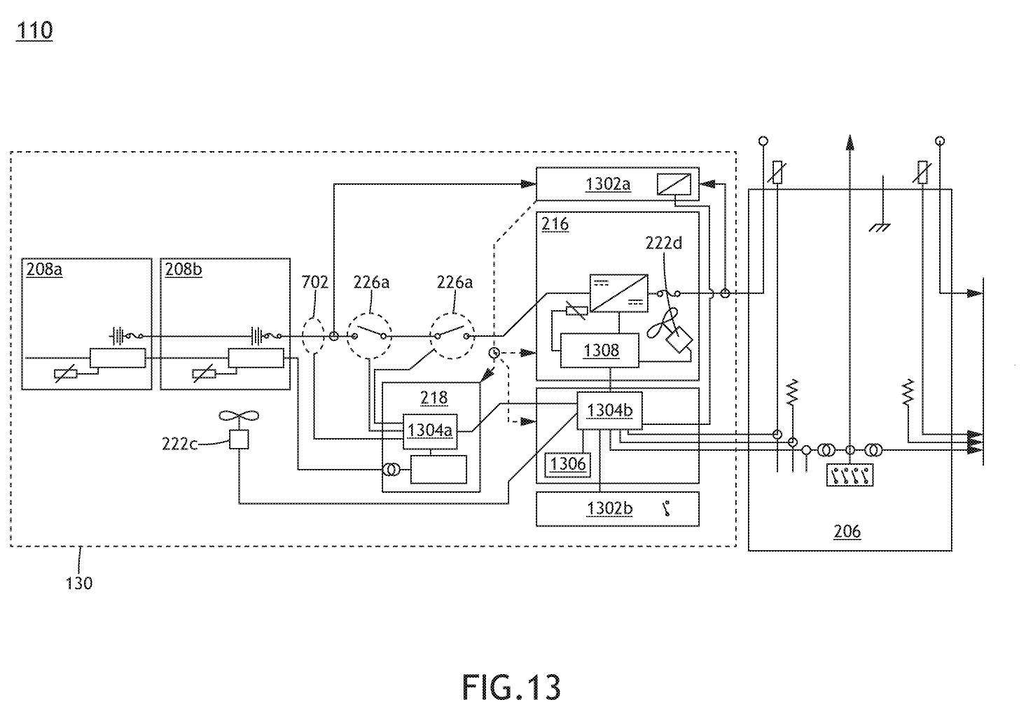

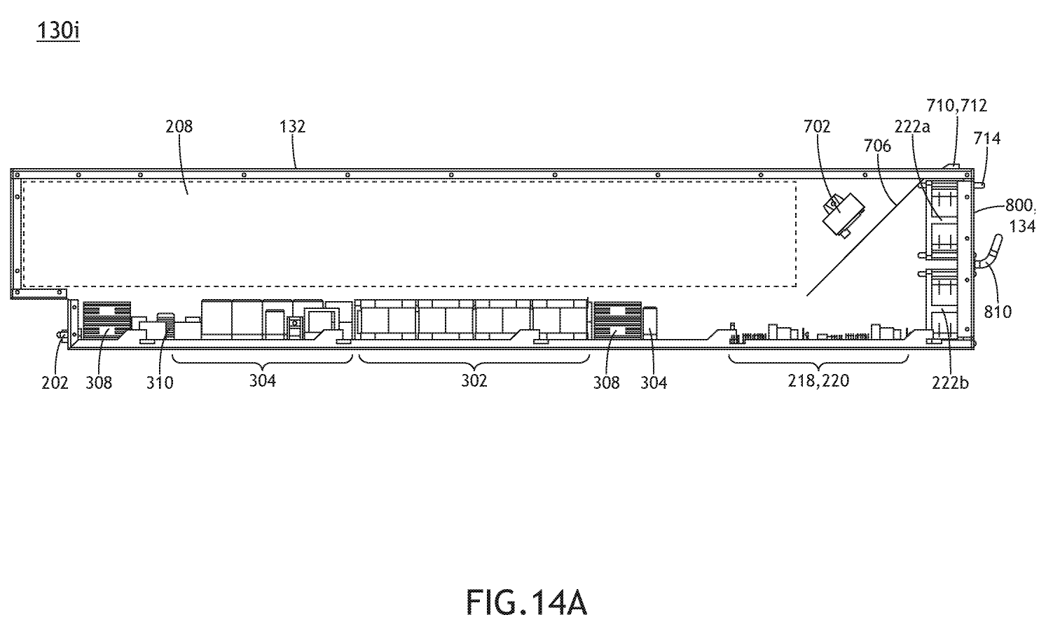

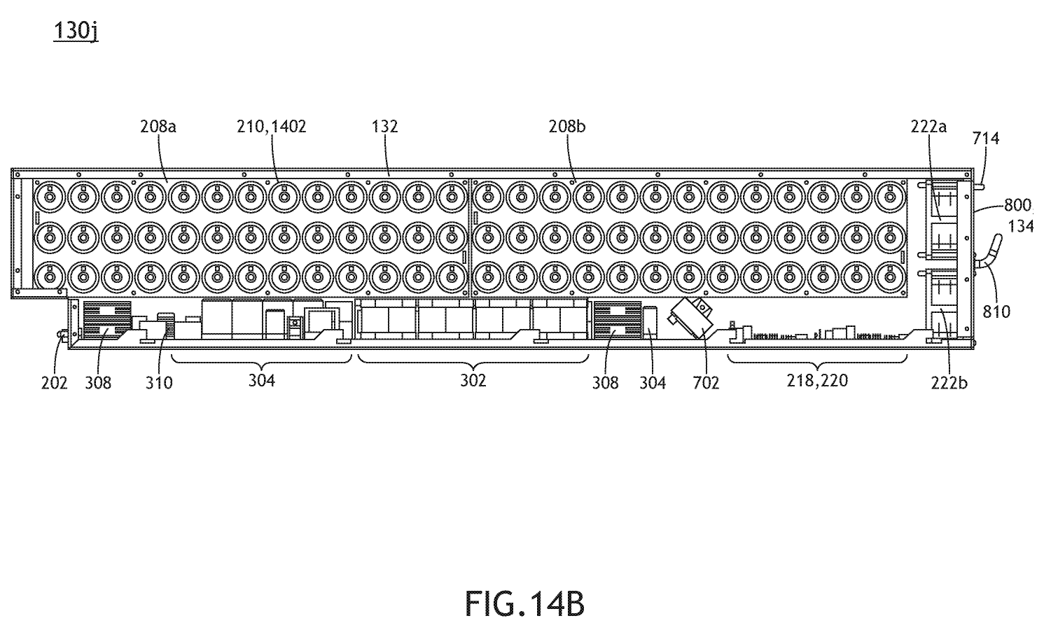

FIG. 9A illustrates a perspective view of a set of power modules 130d, 130e, 130f, 130g, 130h inserted into a housing 900 the power module shelf 200, in accordance with one or more embodiments of the disclosure. Five power modules 130d-h are shown inserted into five of the six docking sites of the power module shelf 200.

In embodiments, the power module shelf 200 includes one or more blanking plates 902 configured to block a movement of air out of one or more vacant or vacated docking sites. For example, as shown in FIG. 9A, only five power modules 130d-h have been fitted within the six available docking sites available on the power module shelf 200. Without blanking plate 902, air forced into the power modules 130d-h by the fans 222a, 222b could leak into the vacant docking site and out of a front end 904 of the power module shelf 200, causing warm air from the power module shelf 200 to mix with cool air intended to enter into the power modules 130d-h. The power module shelf 200 may couple to as many one or more blanking plates 902 needed to cover all vacant docking sites.

FIG. 9B illustrates a perspective view of the blanking plate 902, in accordance with one or more embodiments of the disclosure. The blanking plate 902 may include a lock mechanism 710 (e.g., with prongs 712) and release 714. The blanking plate 902 may further include a handle 810.

FIG. 10A illustrates a perspective rear view of the power module shelf 200, in accordance with one or more embodiments of the disclosure. The power module shelf 200 may include a rear panel 1002 (e.g., a vented rear panel 1002). The rear panel 1002 may be physically coupled to the power connector 204 (e.g., a shelf power clip, such as a shelf power clip with temperature sensors) that is electrically couplable to the one or more busbars 116. The power connector 204 may be configured to receive the input power for the power module 130 and/or send an output power from the power module 130.

The power connector 204 may further include, or be communicatively coupled to, one or more temperature sensors 230. Hidden from view by the rear panel 1002 is the backplane 206 that is electrically coupled to the power connector 204.

FIG. 10B illustrates a perspective rear view of the backplane 206, in accordance with one or more embodiments of the disclosure. The backplane includes a circuit board 1004 electrically coupled to one or more module-shelf connectors 205a, 205b, 205c, 205d, 205e, 205f (e.g., the one or more module-shelf connectors corresponding to the number of docking sites in the power module shelf 200 for power modules 130. The backplane 206 may include one or more electric sub-connectors 1008a, 1008b and backplane sub-componentry 1010 as needed to transmit and receive electrical power and data.

FIG. 11 illustrates a front view of a power sub-system 104, in accordance with one or more embodiments of the disclosure. The energy storage module assembly 110 of the power sub-system 104 is shown occupied by six power module shelves 200a, 200b, 200c, 200d, 200e, 200f, with each shelf 200a-f containing one or more power module 130. The energy storage module assembly 110 may be configured to include any number of power module shelves 200 or docking sites for power module shelves 200. The computer system 100 may be configured to operate with one more of the docking sites for the power module shelves 200 vacant.

FIGS. 12A-12C illustrate wired and perspective views, respectively of an offset standoff 1200, in accordance with one or more embodiments of the disclosure. The offset standoffs 1200 are utilized to create a space between components of an assembly, particularly when aligned standoffs cannot accommodate a necessary spacing or alignment. The offset standoff 1200 may be of any shape. For example, the offset standoff 1200 may be configured as an elliptic cylinder or a rounded rectangular prism (e.g., a stadium prism). The offset standoff 1200 may include one or blocking surfaces 1201a, 1201b and more cavities 1202a, 1202b. For example, the one or more cavities 1202a, 1202b offset standoff 1200 may be used to place over a battery or other energy storage cell 210 within a housing. The energy storage cell 210 would then be prevented from contacting the housing due to the distance between the blocking surface 1201a, 1201b and the distance between a depth 1204 of the one or more cavities 1202a, 1202b and the blocking surface.

FIG. 13 illustrates a simplified schematic of circuitry associated with the power module 130 and the backplane 206 of the power module shelf 200, in accordance with one or more embodiments of the disclosure. Displayed electronic components include the one or more storage energy packs 208, the power converter 216, the one or more contactors, the current transducer 702, and one or more fans 222c, 222d. The power module 130 may further include one or more secondary PCB panels 1302a, 1302b (e.g., for auxiliary power or other functions required by the power module 130).

In embodiments, the power module 130 may include one or more controllers 1304a, 1304b each containing one or more processors. The one or more controllers 1304a, 1304b may provide functionality for one or more steps and processes needed for the power module 130. The power module 130 may include memory (e.g., flash memory) that provide instructions for the one or more controllers 1304a, 1304b.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application-specific integrated circuit (ASIC) devices, one or more field programmable gate arrays (FPGAs), or one or more digital signal processors (DSPs 1308)). In this sense, the one or more processors may include any device configured to execute algorithms and/or instructions (e.g., program instructions stored in memory). In some embodiments, the one or more processors may be embodied as a desktop computer, mainframe computer system, workstation, image computer, parallel processor, networked computer, or any other computer system configured to execute program instructions. Further, the steps described throughout the present disclosure may be carried out by a single controller or, alternatively, multiple controllers. Additionally, power module 130 may include one or more controllers housed in a common housing or within multiple housings.

The memory 1306 may include any storage medium known in the art suitable for storing program instructions executable by the associated one or more processors. For example, the memory 1306 may include a non-transitory memory medium. By way of another example, the memory 1306 may include, but is not limited to, a read-only memory (ROM), a random-access memory (RAM), a magnetic or optical memory device (e.g., disk), a magnetic tape, a solid-state drive and the like. It is further noted that the memory 1306 may be housed in a common controller housing with the one or more processors. In some embodiments, the memory 1306 may be located remotely with respect to the physical location of the one or more processors and the power module 130. For instance, the one or more processors of the power module 130 may access a remote memory (e.g., server), accessible through a network (e.g., internet or intranet).

In embodiments, the power module 130 may be configured to utilize or release approximately 25 kW of power. For example, a power module 130 with a battery-configured storage energy pack 208 may be configured to provide 60 seconds, and up to 90 seconds backup power at 25 kW. In another example, a power module 130 with a supercapacitor-configured storage energy pack 208 may be configured to provide 6.5 kW constant charge-discharge at 35°C, which would provide power conditioning/smoothing for up to 25 kW of a typical GPU load profile. The power module 130 with a supercapacitor-configured storage energy pack 208 also may be configured to provide up to 0.5 seconds or more of backup power at 25 kW.

In embodiments, controllers within the power module 130 are configured to cause the storage energy packs 208 to maintain a specific and/or requested float voltage (e.g., without overshooting). For example, the power module 130 may utilize one or more components within the power module 130 (e.g., battery balance managers 221) to hold the storage energy packs 208 at a specified float voltage. By constraining energy storage to a float voltage, the batteries within the storage energy packs 208 are less stressed, which reduces degradation over time. This control over power storage main be maintained at either the storage energy pack level or the energy storage cell level. For example, the power module 130, via controllers 1304a, 1304b, may cause the one or more energy storage packs 208 to maintain a float voltage if the power module 130 has determined if a first energy storage cell 210 is resting at a higher voltage than a second energy storage cell 210.

In embodiments, the power module 130, via one or more controllers 1304a, 1304b, are configured to cause a change in at least one of a charging current, a float voltage, or a target state of charge for one of the one or more energy storage packs or at least one energy storage cell of one or more energy storage packs. For example a battery management system (e.g., battery balance manager 221), may receive active and/or historical data from one or more energy storage cells 210, as well as customer provided load requirements and/or assumed load requirements in order to adjust power module 130 settings including, but not limited to, allowed charging current, float voltage, and target state of charge. Adjusting these setting may improve the life of the energy storage cells 210.

In embodiments, the power module 130 and/or power module shelf 200 is configured to self-identify a position (e.g., identify a self-position) within the energy storage module assembly 110 and/or power sub-system 104. For example, the power module shelf 200 may be configured to identify its position within the oval rack (e.g., power sub-system 104). In another example, the power module 130 may be configured to identify its position within the power module shelf 200 and/or power sub-system 104. The power sub-system 104 and/or power module shelf 200 may further be configured to determine the total number of power module shelf 200 and/or power module 130 that are available. These determinations may be provided, at least in part, by the one or more controllers 1304a, 1304b, which may provide information on the power module 130 and the power module shelf 200 to the power sub-system 104.

Self-identification by the power module 130 and/or power module shelf 200 may reduce or eliminate a need for service during a power module shelf 200 and/or power module 130 replacement or installation. Self-identification may also make power sub-systems 104 containing a varying number of power module shelves 200 more easily transparent to the controllers (e.g., controllers of the power sub-system 104), facilitating the ability of the power sub-system 104 to determine the capacity of the power sub-system 104 by enumerating through a count of the power module shelves 200 and/or power modules 130. A determination by the power sub-system 104 of the number of power module shelves 200 and power modules 130 may also facilitate hot-swapping of the power module shelves 200 and power modules 130.

In embodiments, one or more components of the power sub-system 104 may be constrained to a specific geometry. For example, the power module 130 may be configured with a length of approximately or substantially 1016 mm. In another example, the power module 130 may be configured with a height of approximately or substantially 192 mm. In another example, the energy storage cells 210 (e.g., supercapacitors) within the storage energy pack 208 may be separated from each other by a vertical (X-axis) distance of approximately or substantially 8.0 mm. In another example, the energy storage cells 210 (e.g., supercapacitors) within the storage energy pack 208 may be separated from each other by a horizontal (Y-axis) distance of approximately or substantially 1.6 mm. In another example, one or more energy storage cells 210 (e.g., supercapacitors) within the storage energy pack 208 may have a diameter of approximately or substantially 33 mm. In another example, one or more energy storage cells 210 (e.g., supercapacitors) within the storage energy pack 208 may have a height (from top to base) of approximately or substantially 68.7 mm.

The power modules 130 described herein may include power modules of 130 different designs, componentry, and/or form factor, while retaining the basic functions of power conditioning. For example, FIG. 14A illustrates a cutaway side view of a power module 130i, in accordance with one or more embodiments of the disclosure. Power module 130i may include one or more components, and placing of components, as power modules 130a-h, and vice versa. The storage energy pack 208 for power module 130i may include batteries as the energy storage cells 210.

FIG. 14B illustrates a cutaway side view of a power module 130j, in accordance with one or more embodiments of the disclosure. Power module 130j may include one or more components, and placing of components, as power modules 130a-i, and vice versa. The storage energy pack 208 for power module 130j may include supercapacitors 1402 as energy storage cells 210.

The herein described subject matter sometimes illustrates different components contained within, or connected with, different other components. It is to be understood that such depicted architectures are merely exemplary, and that in fact many other architectures can be implemented which achieve the same functionality. In a conceptual sense, any arrangement of components to achieve the same functionality is effectively "associated" such that the desired functionality is achieved. Hence, any two components herein combined to achieve a particular functionality can be seen as "associated with" each other such that the desired functionality is achieved, irrespective of architectures or intermedial components. Likewise, any two components so associated can also be viewed as being "operably connected", or "operably coupled", to each other to achieve the desired functionality, and any two components capable of being so associated can also be viewed as being "operably couplable", to each other to achieve the desired functionality. Specific examples of operably couplable include but are not limited to physically mateable and/or physically interacting components and/or wirelessly interactable and/or wirelessly interacting components and/or logically interacting and/or logically interactable components.

Those skilled in the art will recognize that it is common within the art to describe devices and/or processes in the fashion set forth herein, and thereafter use engineering practices to integrate such described devices and/or processes into power and/or data processing systems. That is, at least a portion of the devices and/or processes described herein can be integrated into a data processing system via a reasonable amount of experimentation. Those having skill in the art will recognize that a typical power and/or data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops and control motors (e.g., feedback for sensing position and/or velocity; control motors for moving and/or adjusting components and/or quantities). A typical power and/or data processing system may be implemented utilizing any suitable commercially available components, such as those typically found in power and/or data computing/communication and/or network computing/communication systems.

It is further contemplated that each of the embodiments of the method described above may include any other step(s) of any other method(s) described herein. In addition, each of the embodiments of the method described above may be performed by any of the systems described herein.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.).

While particular aspects of the present subject matter described herein have been shown and described, it will be apparent to those skilled in the art that, based upon the teachings herein, changes and modifications may be made without departing from the subject matter described herein and its broader aspects and, therefore, the appended claims are to encompass within their scope all such changes and modifications as are within the true spirit and scope of the subject matter described herein. Furthermore, it is to be understood that the invention is defined by the appended claims.

What is claimed is:

1. A power module comprising:
a power module housing;
a power connector configured to receive an input power:
one or more energy storage packs configured to store the input power, wherein at least one of the one or more energy storage packs comprises a plurality of energy storage cells;
a battery management system configured to monitor a status of the one or more energy storage packs;
at least one controller configured to control a release of energy from the one or more energy storage packs;
a direct current to direct current (DC-DC) converter configured to convert the energy from the one or more energy storage packs into an output power; and
one or more fans configured to circulate air within the power module.

2. The power module of claim 1, wherein at least one of the plurality of energy storage cells comprises an electrical double layer capacitor.

3. The power module of claim 1, wherein one or more of the one or more energy storage packs comprises:
a pack housing;
a positive terminal; and
a negative terminal, wherein the positive terminal and the negative terminal are disposed on a same end of the pack housing.

4. The power module of claim 3, wherein the DC-DC converter is excluded from the pack housing.

5. The power module of claim 1, wherein the plurality of energy storage cells are arranged in a hexagonal cell pattern.

6. The power module of claim 5, wherein the plurality of energy storage cells are arranged in a triangular cell pattern.

7. The power module of claim 1, wherein one or more of the one or more energy storage packs comprises:
mica tubing; and
an extinguishing patch.

8. The power module of claim 1, wherein the at least one controller is further configured to cause the one or more energy storage packs to maintain a float voltage.

9. The power module of claim 8, wherein causing the one or more energy storage packs to maintain a float voltage comprises determining if a first energy storage cell of the one or more energy storage packs is resting at a higher voltage than a second energy storage cell of the one or more energy storage packs.

10. The power module of claim 1, wherein the at least one controller is further configured to cause a change in at least one of a charging current, a float voltage, or a target state of charge for one of the one or more energy storage packs or at least one energy storage cell of one or more of the one or more energy storage packs.

11. The power module of claim 1, further comprising a baffle disposed within the power module housing and adjacent to an air intake end of the power module, wherein the baffle is configured to direct a movement of air away from the one or more energy storage packs and toward the DC-DC converter.

12. A power system comprising:
one or more power module shelves configured to house a plurality of power modules; and
a plurality of power modules, wherein at least one power module comprises:
one or more energy storage packs configured to receive an input power;
a (DC-DC) converter configured to receive stored power from the one or more energy storage packs and convert the stored power into an output power;
a battery management system configured to monitor a status of the one or more energy storage packs;
at least one controller configured to control a release of output power from the one or more energy storage packs; and
a power connector electrically coupled to the one or more energy storage packs and configured to receive the input power and send the output power.

13. The power system of claim 12, wherein a power module shelf of the one or more power module shelves is configured to accommodate six power modules.

14. The power system of claim 12, further comprising:
a rack configured to store and deliver power to the one or more power module shelves;
a set of rectifier modules electrically coupled plurality of power modules and mechanically couplable to the rack; and
a set of power distribution units electrically coupled to the plurality of power modules and mechanically couplable to the rack.

15. The power system of claim 12, wherein each power module of the plurality of power modules is configured to self-identify a self-position within the power system.

16. The power system of claim 12, further comprising a rack configured to house the one or more power module shelves.

17. The power system of claim 12, wherein the one or more power module shelves further comprises a shelf busbar clip configured to couple to a rack busbar, wherein the shelf busbar clip is electrically coupled to at least one of the power input or the power output of the plurality of power modules.

18. The power module of claim 17, wherein the one or more power module shelves are hot-swappable with the rack busbar while the rack busbar is powered.

19. The power system of claim 12, wherein at least one of the one or more power module shelves comprises a front shelf end, the front end comprising a plurality of docking sites configured to receive the plurality of power modules.

20. The power system of claim 19, further comprising at least one blanking plate couplable to a vacated docking site and configured to block a movement of air out of the one of the one or more power module shelves.
